(19) United States
(12) Patent Application Publication
(10) Pub. No.: US 2013/0083494 A1
(43) Pub. Date: Apr. 4, 2013

(54) THREE-DIMENSIONAL ELECTRONICS PACKAGING

(71) Applicant: Sierra Wireless, Inc., Richmond (CA)

(72) Inventors: Ashish SYAL, Vancouver (CA); Bruce Richard John SAMUELS, Lions Bay (CA); Behrouz POURSEYED, Richmond (CA); Chris MYTTING, Surrey (CA); Audrey SCHERPEREEL, BUC (FR); Paul NEWMAN, Abbotsford (CA)

(73) Assignee: SIERRA WIRELESS, INC., Richmond (CA)

(21) Appl. No.: 13/644,762

(22) Filed: Oct. 4, 2012

Related U.S. Application Data
(60) Provisional application No. 61/542,951, filed on Oct. 4, 2011.

(51) Int. Cl. H05K 7/00

(52) U.S. Cl. 361/735; 361/752

(57) ABSTRACT

Solutions for providing stackable electronics packaging are provided. In some embodiments, electronic components are accommodated in the cavity of a printed circuit board (PCB) or printed circuit assembly (PCA), or co-accommodated in adjoining cavities of adjacent, stacked PCAs or PCBs. The cavities allow for closer stacking of the PCAs or PCBs. In some embodiments, a PCA comprises an encapsulant conformally layered over a PCB with electronic components mounted on top and bottom. Power and/or signal channels are routed through the encapsulant to the top and/or bottom layers. The encapsulated PCAs may be stacked. In various embodiments, stackable PCAs are modular, facilitating customization.

### FIELD OF THE INVENTION

The present invention pertains in general to electronics packaging and in particular to aspects of three-dimensional electronics packaging.

### BACKGROUND

The continuing trend of densifying electronics systems has led to a variety of design challenges. Increased density can have significant benefits, such as increased system speed and efficiency, improved signal synchronization, decreased size, and improved portability. To achieve greater electronics densities, some designers have turned to arranging and interconnecting electronics components in three dimensions. This approach offers higher densities than are achievable with traditional two-dimensional printed-circuit board layouts, but at the cost of increased complexity.

Example approaches to three-dimensional arrangements of electronics components are Stacked System in Package (SiP) technology (for example Chip-stack Multi-chip Modules) and Package on Package (PoP) technology. Stacked SiPs include multiple integrated circuits or semiconductor dies stacked on top of each other and housed in a single package, thereby providing a package with a small horizontal footprint but which may be thicker than traditional packages. In this context, a package refers to a container or carrier housing one or more integrated circuits, for example made of plastic or ceramic material and including pins, leads, solder bumps, or other means of connecting to the integrated circuit. PoP technology involves stacking two or more packages on top of one another. This approach again allows for a smaller horizontal footprint and hence greater electronics density, while also allowing more flexibility to interchange stacked components when compared with SiP.

Printed circuit boards (PCBs) can also be stacked in parallel, for example via mating connectors built in to the PCB surfaces. This allows for greater component density within a given horizontal area, again at the cost of increased complexity.

Although several solutions to three-dimensional arrangements have been proposed and pursued to date, many of these solutions have not yet been fully explored. Many existing solutions suffer from significant drawbacks such as: high cost, complexity, inefficiency of space used, incongruence with supply chain best practices, and lack of flexibility or universal applicability.

Therefore there is a need for configurations of three-dimensional electronics packaging that are not subject to one or more limitations of the prior art.

This background information is provided for the purpose of making known information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide three-dimensional electronics packaging. In accordance with an aspect of the present invention, there is provided a printed circuit module (PCM) comprising a printed circuit board (PCB), the PCM defining at least one cavity and configured for operative coupling with an adjacent PCM in a stacked arrangement, wherein the at least one cavity is configured to at least partially accommodate one or more electronic components, the electronic components operatively mounted either on the PCB or on a PCB of the adjacent PCM.

In accordance with another aspect of the present invention, there is provided a system of two or more printed circuit modules (PCMs) configured for coupling in a stacked arrangement, at least one of the PCMs comprising a printed circuit board (PCB), the PCM defining at least one cavity and configured for operative coupling with an adjacent PCM in a stacked arrangement, wherein the at least one cavity is configured to at least partially accommodate one or more electronic components, the electronic components operatively mounted either on the PCB or on a PCB of the adjacent PCM.

In accordance with another aspect of the present invention, there is provided a printed circuit assembly (PCA) comprising: a printed circuit board (PCB); a set of one or more components mounted to a side of the PCB; an encapsulant conformally provided over the PCB and the set of one or more components; and one or more channels formed through the encapsulant, each of the one or more channels configured to operatively couple a predetermined interior location of the PCA with a predetermined location on a surface of the encapsulant, the predetermined interior location associated with a component of the set of one or more components or a conductor of the PCB.

In accordance with another aspect of the present invention, there is provided a modular electronics system comprising: a socket comprising a first set of electrical connectors configured for interfacing with a printed circuit board; a cavity; and plural subsets of electrical connectors arranged in a stacked configuration along one or more interior sidewalls of the cavity, the first set of electrical connectors operatively coupled with the plural subsets of electrical connectors; and a plurality of electronics modules configured for insertion in the cavity in a stacked configuration, each of the plurality of electronics modules comprising electrical connectors formed around an edge thereof, each of the electronics modules comprising a PCM, said PCM comprising: a printed circuit board (PCB), the PCM defining at least one cavity and configured for operative coupling with an adjacent PCM in a stacked arrangement, wherein the at least one cavity is configured to at least partially accommodate one or more electronic components, the electronic components operatively mounted either on the PCB or on a PCB of the adjacent PCM; wherein each of the plural subsets of electrical connectors is configured for operative engagement of the electrical connectors of a corresponding one of the plurality of electronics modules.

### BRIEF DESCRIPTION OF THE FIGURES

These and other features of the invention will become more apparent in the following detailed description in which reference is made to the appended drawings.

FIG. 1 illustrates, in cross section, a system of stacked printed circuit modules defining cavities therein, in accordance with one embodiment of the invention.

FIG. 2 illustrates, in cross section, a system of stacked printed circuit modules defining cavities therein, in accordance with one embodiment of the invention.

FIG. 3 illustrates, in cross section, a system of stacked printed circuit modules defining cavities therein, in accordance with one embodiment of the invention.

FIG. 4 illustrates, in cross section, a system of stacked printed circuit modules defining cavities therein, in accordance with one embodiment of the invention.

FIG. 5 illustrates, in cross section, a system of stacked printed circuit modules defining cavities therein, in accordance with one embodiment of the invention.

FIG. 6 illustrates, in cross section, a system of stacked printed circuit modules defining cavities therein, in accordance with one embodiment of the invention.

FIG. 7 illustrates, in cross section, a system of stacked printed circuit modules defining cavities therein, in accordance with one embodiment of the invention.

FIG. 8 illustrates, in cross section, a system of stacked printed circuit modules defining cavities therein, in accordance with one embodiment of the invention.

FIG. 9 illustrates a socket for coupling to a printed circuit board, and configured to receive stacked electronics modules therein, in accordance with embodiments of the invention.

FIG. 10 illustrates a portion of a stacked connector provided within the socket of FIG. 9 and configured for electrically coupling to the stacked electronics modules.

FIG. 11 illustrates a coupling between pins of the stacked electronics modules and the stacked connector of FIG. 10.

FIG. 12 illustrates a socket for coupling to a printed circuit board, and configured to receive stacked electronics modules therein, in accordance with another embodiment of the invention.

FIG. 13 illustrates, in cross section, a stackable, encapsulated printed circuit assembly provided in accordance with an embodiment of the present invention.

FIG. 14 illustrates, in cross section, a stackable, encapsulated printed circuit assembly provided in accordance with another embodiment of the present invention.

FIG. 15 illustrates a stacked arrangement of plural encapsulated printed circuit assemblies, in accordance with an embodiment of the present invention.

FIG. 16 illustrates a stacked arrangement of plural encapsulated printed circuit assemblies, in accordance with another embodiment of the present invention.

### DETAILED DESCRIPTION OF THE INVENTION

### Definitions

The term “Printed Circuit Board” or “PCB” refers to a single-sided, double-sided, or multilayer printed circuit board to which components may be attached, for example by soldering.

The term “Printed Circuit Assembly” or “PCA” refers to a PCB along with electronics components, such as chips, and/or other structural components such as frames or spacers attached thereto.

The term “Printed Circuit Module” or “PCM” is used generically to refer to either a PCB or a PCA. A PCM may or may not include an encapsulant.

The term “Chip” refers to a packaged electronic device, such as a semiconductor device, integrated circuit, set of semiconductor devices or integrated circuits, or the like. The package may be a plastic chip carrier, ceramic chip carrier, or other suitable package. The package typically comprises one or more electrical connectors such as pins, pads, leads, apertures, vias, solder balls, solder bumps, or the like, operatively coupled to the electronic device therein. Standard chip carriers include BGAs, LGAs, PLCCs, DIPs, SOICs, and numerous other chip carriers as would be readily understood by a worker skilled in the art.

The term “encapsulant” or “conformal encapsulant” refers to a generally insulating material which is applied to a PCA and forming around the PCA components in a conformal manner. For example, the encapsulant may be applied as a fluid or spray-on coating, which contacts the PCA components and cures into a solid encapsulant with a perimeter. The perimeter may be formed in a desired manner, for example to form a cube, rectangular prism, or other shape. Encapsulants applied to PCAs are generally electrically insulating, and may also be electromagnetically insulating. Encapsulants may be provided having desired thermal conduction properties, predetermined physical properties such as strength, plasticity, elasticity, and the like. Although an encapsulant may conform, along its inner surface, to a PCA having a variable topography, the outer surface of the encapsulant may have a substantially different topography. In particular, the outer surface of the encapsulant may be flat, thereby facilitating stackability of an encapsulated PCA.

As used herein, the term “about” refers to a +/−10% variation from the nominal value. It is to be understood that such a variation is always included in a given value provided herein, whether or not it is specifically referred to.

Unless defined otherwise, all technical and scientific terms used herein have the same meaning as commonly understood by one of ordinary skill in the art to which this invention belongs.

Aspects of the present invention generally relate to three-dimensional, stackable electronics packaging such as chips and printed circuit assemblies (PCAs). Embodiments of the present invention may provide for particular desirable features, such as increased density of electronics relative to circuit area, modularity and interchangeability of electronic components, physical and electrical standardization of component interconnection, improved ease of interconnection of stacked components, and the like.

Increased density of electronics may facilitate a more efficient use of limited space, which may be desirable for example in portable electronics devices. Increased electronics density may also result in lower and/or more predictable signal propagation delay between components, thereby improving system speed, efficiency, and signal synchronization.

Three-dimensional stacking of electronic components may facilitate an increase in options and flexibility for component interconnections, which may otherwise be limited for example when restricted to routing traces on a planar printed circuit board. For example, by arranging components in three dimensions rather than two dimensions, an additional degree of freedom is provided in which to layout the device components and the interconnections between such components. This may simplify design and electrical trace layout, allow components to be placed nearer to or further from each other as desired, and the like. Device layout may further take advantage of this additional degree of freedom to optimize considerations such as performance and overall footprint.

In embodiments of the present invention, certain sets of modules are provided having standardized physical dimensions, a standardized pinout or arrangement of connections, and optionally standardized functionality, standardized power and ground requirements, or the like. This provides for a substantial degree of interchangeability among modules of a set. In some embodiments, stacking order of a plurality of standardized modules may be adjusted without affecting functionality.

Embodiments of the present invention provide for stackable electronic modules, which may facilitate the incorporation of multiple and/or customizable wireless network capabilities into existing wireless communication products, at the time of product assembly, without changing the size, shape, and/or general layout of major product components, such as housing and motherboard. Wireless communication products may include handheld electronic devices such as cellular devices, or wireless communication components for coupling to another electronic device, such as a remote device. The stackability aspect can be beneficial for wireless communication products, or indeed other electronics products, which are installed into size constrained places. Certain changes in size and/or shape of the product might be unacceptable due to size constraints. For example, if separate modules were provided side by side on a circuit board instead of stacked as provided for in embodiments of the present invention, the wireless communication product might become larger, which would be problematic due to the size constraints. By stacking modules, already existing surplus space inside the product may be utilized, while also avoiding the need to modify components such as the motherboard in order to accommodate additional or different modules.

Embodiments of the present invention facilitate “mixing and matching” of wireless modules in a wireless communication product, so as to provide a variety of wireless communication capabilities. For example, different wireless communication capabilities, such as the capability to communicate via a standardized communication protocol or set of protocols, may be used for accessing different wireless networks. By providing modular flexibility, embodiments of the present invention may enable a wider variety of customers to be served. Manufacturing and device certification costs might otherwise preclude providing separate combined products for any but the most popular combinations.

### Stackable PCAs with Cavities

In accordance with an aspect of the present invention, there is provided a printed circuit module (PCM) comprising a printed circuit board (PCB), with the PCM defining at least one cavity. The PCM is configured for coupling with at least one adjacent PCM in a stacked arrangement, for example by mating a non-cavity portion of the PCM with a corresponding portion of the adjacent PCM. At least one cavity defined by the PCM is configured to at least partially accommodate one or more electronic components. The electronic components either form part of the PCM or part of the adjacent PCM. Generally, the electronic components are mounted directly or indirectly on a PCB of the corresponding PCM. A perimeter of the PCM may be configured for coupling with an adjacent PCM. In some embodiments, electronic components of the PCM may be at least partially accommodated within the perimeter.

In some embodiments, the PCM may be a printed circuit assembly, comprising one or more spacers mounted to a PCB thereof. The spacers generally act as extensions of the PCB, with at least some sidewalls of the spacers defining sidewalls of the PCM cavities. Thus, the spacers may at least partially define the PCM cavities. Tops of the spacers may comprise electrical connectors, such as pads, pins, solder balls, conductive apertures, or the like, which may be configured for operatively coupling to mating electrical connectors of an adjacent, stacked PCM. These electrical connectors may be electrically coupled to other elements of the PCM, for example PCB pads or traces.

In some embodiments, the spacers may comprise a frame formed around a perimeter of the PCB. The spacers or frames may be interposed between adjacent stacked PCBs, thereby providing increased space for accommodating components which may protrude from the PCB surface. The spacers or frames may be considered part of the PCA comprising the PCB to which they are attached. In some embodiments, such spacers or frames may be used in combination with cavities formed in the PCB surface as described below.

In some embodiments, the PCB comprises a surface layer and an interior layer, and the at least one cavity of the PCM is formed in the surface layer and extends to the interior layer. Various methods of manufacturing PCBs having cavities therein, and of mounting components within these cavities are known in the art. Thus, in accordance with some embodiments of the present invention, there is provided a printed circuit board (PCB) comprising a surface layer, an interior layer, and at least one cavity formed in the surface layer and extending to the interior layer. The surface layer is configured for coupling with an adjacent PCB in a stacked arrangement. The cavity is configured to at least partially accommodate one or more electronic components, which are electronic components mounted either on the PCB or on the adjacent PCB.

For example, cavities may be provided by removing or excluding predetermined portions of one or more PCB layers. For example, one or more conducting and insulating layers of a multilayer PCB may be removed or excluded.

As will be readily understood by a worker skilled in the art, difficulties associated with mounting and soldering of components in a cavity may increase with cavity depth. As such, embodiments of the present invention may be used with substantially low-profile components, such as ultra-small capacitors or low-profile packages, thereby avoiding such difficulties. In some embodiments, cavity mounting difficulties may be partially or fully avoided by housing the component at least partially within a cavity of the adjacent PCB. This allows the component to be mounted on a non-cavity or shallow-cavity surface of its host PCB, rather than in a deep cavity. For example, a component may be accommodated partially by a cavity of its host PCB and partially by a facing cavity of an adjacent PCB. The facing cavity portion of the adjacent PCB may or may not have components mounted therein.

In some embodiments, as will be described elsewhere herein, cavities of a PCM may be defined at least in part by an encapsulant conformally applied to the PCM.

In some embodiments, plural stackable PCMs may be operatively interconnected by mating connectors. Connectors may be mounted on a non-cavity portion of a PCM, for example on a PCB surface or spacer surface. The connectors and, if applicable, spacers, may be configured to provide a predetermined distance between the PCBs of adjacent PCMs.

In some embodiments, plural stackable PCMs may be operatively interconnected by direct contact and soldering between the PCBs thereof. Surface traces of adjacent PCBs may be routed so as not to contact each other undesirably, or insulating material may be applied to portions of the otherwise contacting PCBs. For example, an insulating layer of predetermined thickness may be conformally applied to one or both PCB surfaces in appropriate regions.

In some embodiments, at least one of the stackable PCAs may be used as an interposer for mounting components to a relatively large host PCB. Stackable PCAs may be mounted in one or more locations on the host PCB.

In embodiments of the present invention, the cavity depth of a PCM is greater than or equal to the height of the components of the same PCM. Thus, the entirety of a cavity-mounted component may be held within the host PCM cavity.

In some embodiments, a component may be mounted on a non-cavity portion of a first PCM, and the entirety of the component may be held within a cavity of a second PCM when stacked with the first PCM.

In some embodiments, a cavity-mounted component of a PCM may be held partially within the cavity of the same PCM, and held partially within a cavity of an adjacent PCM when stacked with the first PCM. The two cavities face and communicate with each other, thereby forming a compound cavity.

In accordance with embodiments of the present invention, there is provided a system of two or more printed circuit modules (PCMs) configured for coupling in a stacked arrangement as described herein. At least one of the PCMs defines a cavity, wherein the cavity is configured to at least partially accommodate one or more electronic components, such as components mounted either on the PCB thereof or on a PCB of the adjacent PCM.

In some embodiments of the above system, a first cavity is defined by a first PCM of the system, and a second cavity is defined by a second, adjacent PCM of the system. The first cavity faces and is in communication with the second cavity when the first PCM and the second PCM are in the stacked arrangement. The first and second cavities may thus be configured to accommodate electronic components in various configurations. For example, the first cavity may entirely accommodate components of the first PCM. As another example, the second cavity may entirely accommodate components of the second PCM. As another example, the first and second cavities may each accommodate a portion of a component of the first PCM, such that both cavities together entirely accommodate the component. The above examples are not mutually exclusive. For example, some components of a PCM may be entirely accommodated in the cavity thereof, while other components of the same or an adjacent PCM may be accommodated by cavities of two adjacent PCMs.

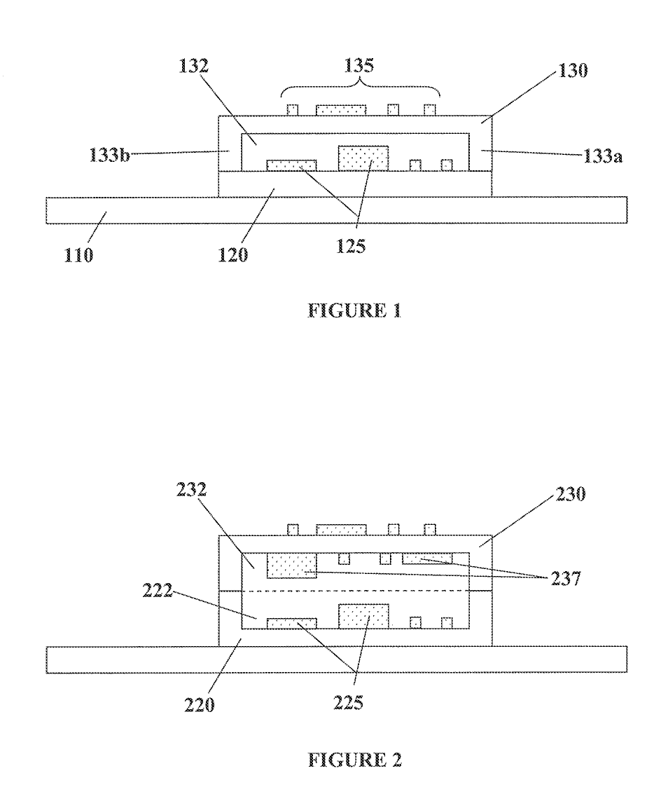

FIGS. 1 to 8 illustrate, in cross section, stacked printed circuit modules defining cavities in accordance with various exemplary embodiments of the present invention. It is to be understood that the present invention may also comprise variations and combinations of the illustrated systems, which are described below.

FIG. 1 illustrates a PCM 130 stacked with an adjacent PCM 120. The PCM 120 may optionally be mounted on a host PCB 110. The host PCB 110 may be substantially larger than the stacked PCMs 120 and 130. The host PCM may comprise other components, stacks of PCMs, or the like. The PCM 130 comprises a cavity 132 on its bottom side which accommodates electronic components 125 mounted on the top side of the PCM 120, adjacent to the bottom side of the PCM 130. The PCM 130 may optionally comprise components 135 on its top side. As illustrated, the PCM 130 has no components mounted on its bottom side. This avoids having to mount components within the cavity 132, and also allows for increased clearance in the cavity 132 for accommodating components 125. The illustrated arrangement avoids requiring any cavity-mounted components on either PCM 120 or 130, while retaining stackability benefits provided by the cavity 132.

FIG. 1 further illustrates side portions 133a and 133b, which define the cavity 132. The side portions 133a and 133b engage with the PCM 120, and may be attached thereto, for example by direct soldering or connectors. The side portions 133a and 133b may be integral to the PCB of the PCM 130, for example when a cavity is formed by cutting into the PCB. The side portions 133a and 133b may correspond to spacers, frames, or the like.

FIGS. 2 to 7 also comprise side portions similar to the side portions 133a and 133b of FIG. 1. FIGS. 2 to 6 may comprise a host PCB, similar to host PCB 110, onto which the PCMs are stacked. FIGS. 2 to 6 may optionally comprise components mounted on a top side of the topmost PCM, similar to components 135.

FIG. 2 illustrates a PCM 220 stacked with an adjacent PCM 230. The PCM 220 comprises a cavity 222 with components 225 mounted therein. The PCM 230 comprises a cavity 232 with components 237 mounted therein. The two cavities 222 and 237 face and communicate with each other to form a contiguous cavity between the two stacked PCMs 220 and 230.

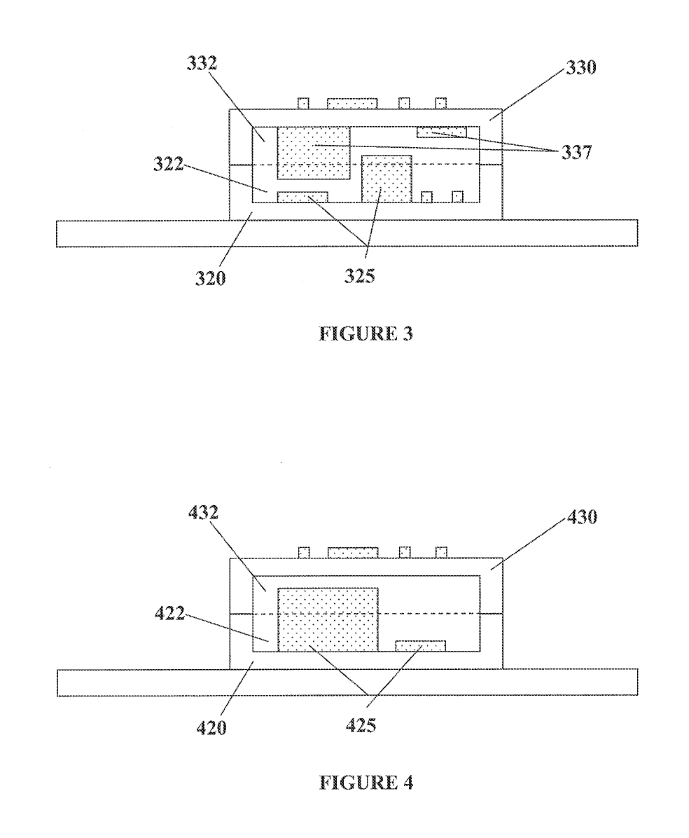

FIG. 3 illustrates a PCM 320 stacked with an adjacent PCM 330. The PCM 320 comprises a cavity 322 with components 325 mounted therein. The PCM 330 comprises a cavity 332 with components 337 mounted therein. The two cavities 322 and 337 face and communicate with each other to form a contiguous cavity between the two stacked PCMs 320 and 330. As illustrated, at least some components 337 of the top PCM 330 are partially accommodated by the cavity 332 of the top PCM 330, and partially accommodated by the cavity 322 of the bottom PCM 320. Similarly or alternatively, at least some components 325 of the bottom PCM 320 are partially accommodated by the cavity 322 of the bottom PCM 320, and partially accommodated by the cavity 332 of the top PCM 330. By allowing components to be accommodated partially by the cavity of an adjacent PCM, cavities may be made shallower, and hence difficulties with mounting components within deep cavities may be reduced or avoided.

FIG. 4 illustrates a PCM 420 stacked with an adjacent PCM 430. The PCM 420 comprises a cavity 422 with components 425 mounted therein. The PCM 430 comprises a cavity 432 without components mounted therein. The two cavities 422 and 437 face and communicate with each other to form a contiguous cavity between the two stacked PCMs 420 and 430. As illustrated, at least some components 425 of the bottom PCM 420 are partially accommodated by the cavity 422 of the bottom PCM 420, and partially accommodated by the cavity 432 of the top PCM 430. Alternatively, (not illustrated) the components 425 may be removed and at least some components of the top PCM 430 are partially accommodated by the cavity 432 of the top PCM 430, and partially accommodated by the cavity 422 of the bottom PCM 420. By allowing components to be accommodated partially by the cavity of an adjacent PCM, cavities may be made shallower, and hence difficulties with mounting components within deep cavities may be reduced or avoided. The cavities may also be made shallower by mounting components in only one of the two facing cavities.

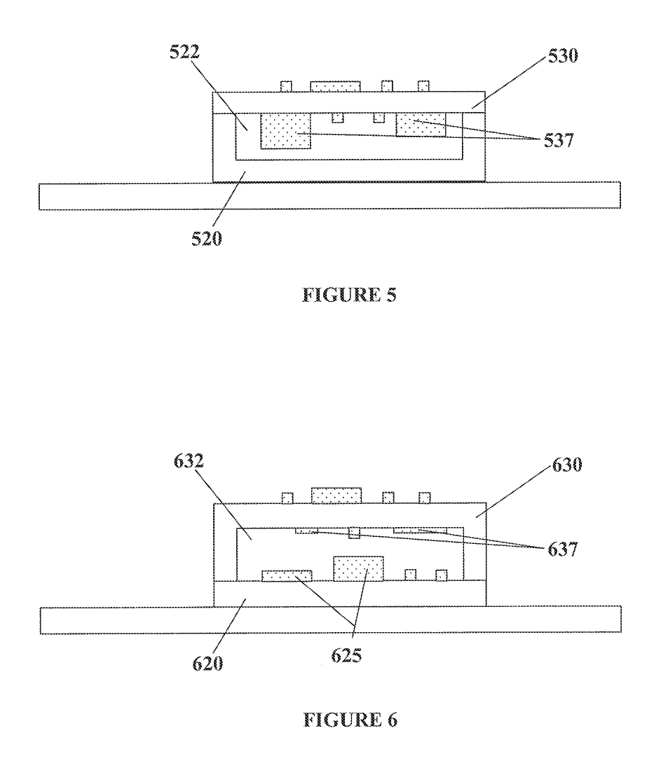

FIG. 5 illustrates a PCM 520 stacked with an adjacent PCM 530. The bottom PCM 520 comprises a cavity 522 without components mounted therein. The top PCM 530 comprises components 537 mounted on a bottom side non-cavity surface, the components 537 accommodated within the cavity 522. This arrangement avoids having to mount components within a cavity.

FIG. 6 illustrates a PCM 620 stacked with an adjacent PCM 630. The PCM 630 comprises a cavity 632 on the side facing the PCM 620. The PCM 620 comprises components 625 mounted on a non-cavity surface, the components 625 accommodated within the cavity 632. The PCM 630 comprises components 637 mounted within the cavity 632. The components 625 and 637 are shared within the cavity 632. This may be achieved by selecting and arranging components such that there is always clearance between the components 625 and 637.

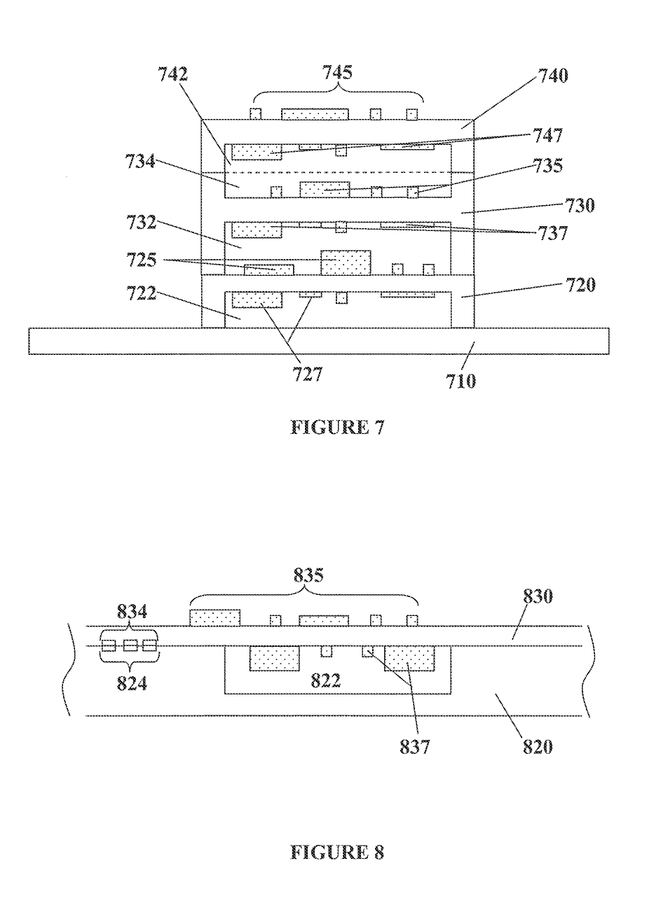

FIG. 7 illustrates a host PCB 710, onto which at least three PCMs 720, 730, and 740 are stacked. The lower PCM 720 is coupled to the host PCB 710, and comprises a cavity 722 facing the host PCB 710. The cavity 722 accommodates components 727 of the lower PCM 720, optionally along with components of the host PCB 710. The middle PCM 730 is coupled on top of the lower PCM 720, and includes a lower cavity 732 facing the lower PCM 720. Components 725 on the top of the lower PCM 720 and components 737 on the bottom of the middle PCM 730 are accommodated within the cavity 732. The upper PCM 740 is coupled on top of the middle PCM 730, and includes a cavity 742 facing the middle PCM 730. The middle PCM also includes an upper cavity 734 on its upper surface which communicates with the cavity 742 of the upper PCM 740. The middle PCM 730 comprises components 735 at least partially accommodated within the upper cavity 734 and optionally partially accommodated within the cavity 742 of the upper PCM 740. The upper PCM 740 comprises components 747 at least partially accommodated within the cavity 742 and optionally partially accommodated within the upper cavity 734 of the middle PCM 730. The upper PCM 740 may also comprise components 745 on its upper surface.

FIG. 8 illustrates a PCB 820 having a cavity 822 formed therein. The cavity 822 may be formed by cutting into the PCB 820. The cavity may be cut through one or more layers of a multilayer PCB, and may be cut partway through a PCB insulating layer. The cavity may or may not terminate at a conductive interior layer of the PCB 820. A PCB 830 is coupled to the PCB 820. The PCB 820 may comprise electrical connectors 824, such as pads, which mate with corresponding electrical connectors 834 of the PCB 830. The upper PCB 830 comprises components 837 mounted on a lower surface and accommodated within the cavity 822 of the lower PCB 820. The upper PCB 830 may also comprise components 835 mounted on an upper surface.

In some embodiments, there is provided a printed circuit assembly (PCA) comprising a printed circuit board (PCB), the PCA defining a perimeter configured for coupling with at least one adjacent PCM in a stacked arrangement, the PCA comprising one or more electronic components at least partially accommodated within the perimeter, the electronic components mounted in at least one cavity of the PCA, covered with an encapsulant, or both.

In some embodiments, there is provided a system of two or more printed circuit modules (PCMs) configured for coupling in a stacked arrangement, at least one of the PCMs defining a cavity, wherein the cavity is configured to at least partially accommodate one or more electronic components, the electronic components mounted either on the PCB or on a PCB of the adjacent PCM.

In some embodiments, there is provided a printed circuit board (PCB) comprising a surface layer, an interior layer, and at least one cavity formed in the surface layer and extending to the interior layer, the surface layer configured for coupling with an adjacent PCB in a stacked arrangement, wherein the cavity is configured to at least partially accommodate one or more electronic components, the electronic components mounted either on the PCB or on the adjacent PCB.

### Stackable Electronics Modules with Edge Contacts in Socket Housing

In accordance with an aspect of the present invention, there is provided a PCB-mountable socket for coupling electronics with a printed circuit board. The socket comprises a first set of electrical connectors configured for interfacing with the printed circuit board, for example pins, pogo pins, pads, solder balls, leads, grid arrays thereof, or the like mounted on the bottom of the socket. The socket further comprises a cavity configured to receive a plurality of electronics modules in a stacked configuration. The cavity comprises a second set of electrical connectors configured for interfacing with the plurality of electronics modules. For example, the second set of electrical connectors may be spring-type electrical connectors mounted in an array on the cavity sidewalls. At least one of the second set of electrical connectors is operatively coupled with at least one of the first set of electrical connectors.

In accordance with another aspect of the present invention, there is provided a modular electronics system comprising: a socket comprising a first set of electrical connectors configured for interfacing with a printed circuit board; a cavity; and plural subsets of electrical connectors arranged in a stacked configuration along one or more interior sidewalls of the cavity, the first set of electrical connectors operatively coupled with the plural subsets of electrical connectors; and a plurality of electronics modules configured for insertion in the cavity in a stacked configuration, each of the plurality of electronics modules comprising electrical connectors formed around an edge thereof; wherein each of the plural subsets of electrical connectors is configured for operative engagement of the electrical connectors of a corresponding one of the plurality of electronics modules.

In embodiments of the present invention, the electrical connectors mounted in the cavity comprise plural subsets of electrical connectors in a stacked configuration, each of the plural subsets configured for engaging corresponding electrical connectors formed around an edge of a respective one of the plurality of electronics modules. The electrical connectors may be resilient or spring-type connectors, which are configured to both electrically and grippingly engage the electronics modules. Various spring-type connectors, such as pogo pins, resilient bent metal contacts, and the like, as would be readily understood by a worker skilled in the art.

In accordance with a related aspect of the present invention, there is provided a modular electronics system comprising a socket and a plurality of electronics packages for housing in the socket in a stacked arrangement. Each of the plurality of electronics packages comprises electrical connectors formed around an edge thereof. Each of plural subsets of the socket electrical connectors are configured for operative engagement of the electrical connectors of a corresponding one of the plurality of electronics packages.

In embodiments of the present invention, the electronics modules are chips, such as chips housed in a leadless chip carrier such as a PLCC. The chips comprise conductive connectors, such as pins, pads, leads, or the like, arranged for example around the chip edge, and configured for coupling with a subset of the electrical connectors mounted on the socket cavity sidewalls.

In some embodiments, the electronics modules are printed circuit modules (PCMs), which are generally substantially smaller than the PCB onto which the socket is mounted. The PCMs may or may not comprise cavities and/or encapsulating layers as described elsewhere herein. Such PCMs may comprise a plurality of traces or pads arranged in a predetermined pattern along the PCB edge, such that the these traces or pads contact and couple with a subset of the electrical connectors mounted on the socket cavity sidewalls.

In some embodiments, each of the stackable electronics modules corresponds to a functional hardware module, which may optionally interoperate with other modules. A plurality of modules may be provided, each having a common interconnection pattern. Modules may then be selected and operatively coupled in the socket housing during assembly. This facilitates flexible configuration and customization at assembly time.

In some embodiments, the stackable electronics modules may comprise top and bottom connectors in addition to the edge connectors, for example for routing power, ground, or certain signals to various chips. This provides for improved flexibility in interconnection of adjacent chips, as there are more possible signal routes.

In some embodiments, the stackable electronics modules may comprise traces patterned on the outside surface thereof, interconnecting different connectors. The traces may be formed on chip-type electronics modules after they have been manufactured. Such traces, which may be recessed or which may comprise an insulating layer on top, may allow for improved flexibility in interconnection of adjacent chips.

In some embodiments, the walls of the socket may comprise one or more layers of wiring, circuit traces, or the like, for routing connections between board connections of the socket and chip connections of the socket.

In some embodiments, different stackable electronics modules may correspond with functional modules, which may be selected and provided during assembly to satisfy desired cost and/or functional requirements. For example, a chip module capable of operating a desired wireless communication protocol may be selected and inserted into the socket, depending on geography, functional requirements, and the like. A generic device such as a cell phone may then be manufactured and enabled for a particular wireless communication protocol corresponding to a particular service provided and/or geographic region.

In some embodiments, connectivity between the socket module and a bottom surface of a lowermost electronics module may be made via pogo pins, or other resilient non-solder connector. In some embodiments, the socket module may comprise a BGA or PGA socket along its bottom surface for receiving corresponding balls or pins of a chip module.

In some embodiments, connectivity between a top surface of a stackable electronics module and a bottom surface of an adjacent electronics module may be made via resilient non-solder connectors, such as pairs of mating and protruding spring connectors.

The socket may be configured to require a predetermined amount of insertion force, for example required to overcome the spring pin resilience. In some embodiments, the socket may be configured to require substantially zero insertion force (ZIF socket), for example by inclusion of one or more lever mechanisms operatively coupled to the socket, which separates the spring contacts prior to insertion and engages the spring contacts after insertion, as would be readily understood by a worker skilled in the art.

Embodiments of the present invention may resemble a vertical stack of PLCC sockets. PLCC sockets are generally known in the art and comprise spring-type connectors for engaging edge connectors of a PLCC package. Each PLCC chip may be inserted and pushed down within the socket, thereby making room for insertion of an additional PLCC chip on top, until the socket is filled. This arrangement may facilitate densification of electronics, close coupling of electronics for improved integration, and the like.

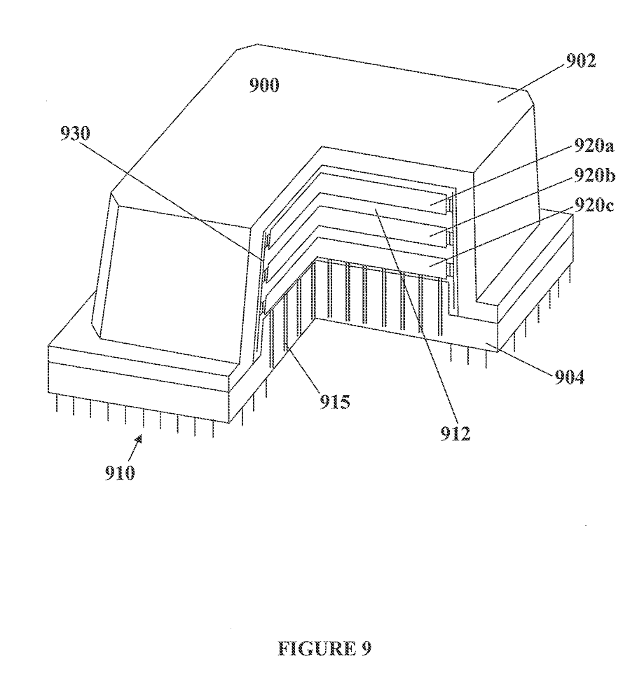

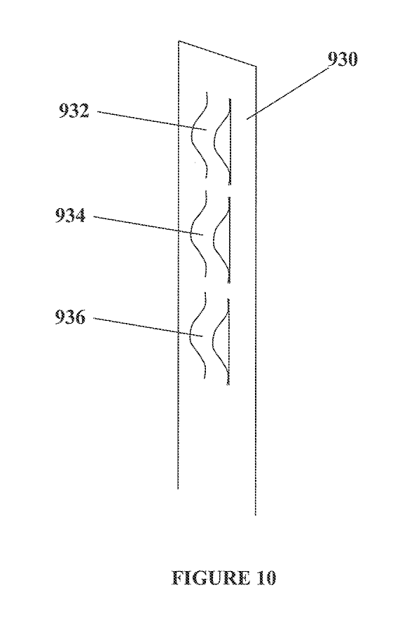

FIG. 9 illustrates a socket 900 for coupling to a printed circuit board (not shown) via electrical connectors 910, such as pins, pads, solder balls, or the like. The socket 900 comprises an enclosed cavity 912 configured to receive stacked electronics modules 920a, 920b, 920c, such as chips. Optionally, the socket 900 comprises pins 915, such as pogo pins, which may mate with a bottom module 920c, the circuit board, or both. Electrical connectors, such as connectors 930 are provided on sidewalls of the cavity 912 in an array configuration. Each of a plurality of connectors is configured for mating engagement with a corresponding connector of an electronics module. The connectors of the socket 900 may be spring-type connectors, for example. Each electronics modules comprises connectors, such as pins or pads, on sides thereof for such mating engagement.

As illustrated, the socket 900 includes a cap portion 902 and a base portion 904. The cap portion 902 and the base portion 904 may be separated for assembly, at which time the electronics modules 920a, 920b, 920c are fitted within the cap portion 902. The cap portion 902 may then be affixed to the base portion 904 via adhesive, screws, snaps, or other connectors and the assembled socket affixed to a circuit board. Alternatively, an aperture (not shown) may be formed in the top of the cap portion 902 for inserting electronics modules into the socket even when the cap portion and base portion are connected. The socket 900 may be sealed after assembly to prevent tampering or unauthorized disassembly. Alternatively, in some embodiments the socket 900 may be configured so that it may be re-opened after assembly and the modules serviced, replaced, or switched by a technician if desired. This may be useful during prototyping or early product life, for example.

FIG. 10 illustrates a portion of a stacked connector 930 provided within the socket 900. Plural such stacked connectors may be arranged side by side on one or more sidewalls of the cavity 912 of the socket 900. Each connector may be electrically coupled, via wires or traces within the socket housing, to the electrical connectors 910, thereby facilitating coupling between the electronics modules and the printed circuit board. The stacked connector 930 may be inserted into a slot along the edge of the socket interior, the slot having been provided for this purpose.

Each stacked connector portion 930 comprises plural resilient spring-type connectors 932, 934, 936, for example in the form of metallic protrusions. The connectors 932, 934, 936 are configured for electrically and frictionally engaging corresponding connectors of the electronics modules when inserted into the cavity.

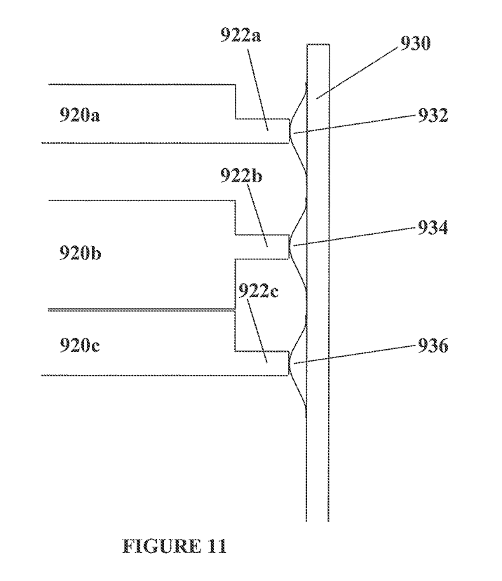

FIG. 11 illustrates contact between pins 922a, 922b and 922c and the connectors 932, 934, 936 of the stacked connector portion 930 illustrated in FIG. 10. Each pin is a representative pin corresponding to a respective stacked electronics module 920a, 920b, 920c. Each electronics module will typically have multiple pins, for example arranged in a plane as would be readily understood by a worker skilled in the art. In some embodiments, the stacked electronics modules 920a, 920b, 920c are in close proximity or even in contact with each other. This arrangement is illustrated by the close proximity between modules 920b and 920c. By stacking the electronics modules in close proximity or in contact with each other, the assembly may be made resilient to mechanical shock which might otherwise tend to disconnect the pins from the spring connectors. Assembly may also be simplified since each module is simply inserted as far as possible into the socket. If electronics modules are to be in close proximity and/or in contact, manufacturing of these modules may require tight control in order to provide modules of an appropriate thickness. In some embodiments, if a functional electronics module is not required at a certain level, a “dummy” spacer module may be inserted in its place. This may provide for a more mechanically resilient package, since the spacer modules may help to keep the other modules in place if the socket is subjected to mechanical shock.

In some embodiments, the pins 922a, 922b and 922c engage and compress their respective resilient spring connectors 932, 934, 936 in order to maintain adequate physical and electrical contact.

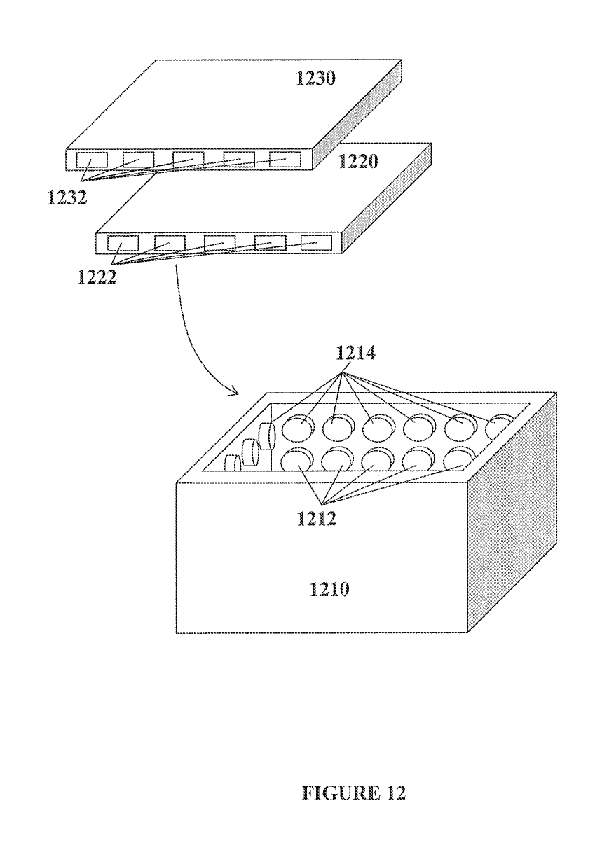

FIG. 12 illustrates a socket 1210 for coupling to a printed circuit board, and configured to receive stacked electronics modules 1220, 1230, therein, in accordance with another embodiment of the invention. The socket comprises at least a first subset of connectors 1212, such as pins or pads, configured to engage with corresponding electrical connectors 1222 of the electronics module 1220 when inserted in the socket generally at the height of the first subset. The socket further comprises at least a second subset of connectors 1214, such as pins or pads, configured to engage with corresponding electrical connectors 1232 of the electronics module 1230 when inserted in the socket generally at the height of the second subset. The socket 1210 comprises a top aperture through which electronics modules may be inserted. A cap may optionally be affixed over the top aperture after the electronics modules are inserted.

In some embodiments, there is provided a socket for coupling electronics with a printed circuit board, the socket comprising: a first set of electrical connectors configured for interfacing with the printed circuit board; and a cavity configured to receive a plurality of electronics modules in a stacked configuration, the cavity comprising a second set of electrical connectors configured for interfacing with the plurality of electronics modules, at least one of the second set of electrical connectors operatively coupled with at least one of the first set of electrical connectors. Optionally, one or more of the electronics modules is a chip or a printed circuit module. Optionally, the second set of electrical connectors comprises plural subsets of electrical connectors in a stacked configuration, each of the plural subsets configured for engaging corresponding electrical connectors formed around an edge of a respective one of the plurality of electronics modules.

In some embodiments, there is provided a modular electronics system comprising: a socket comprising a first set of electrical connectors configured for interfacing with a printed circuit board; a cavity; and plural subsets of electrical connectors arranged in a stacked configuration along one or more interior sidewalls of the cavity, the first set of electrical connectors operatively coupled with the plural subsets of electrical connectors; and a plurality of electronics modules configured for insertion in the cavity in a stacked configuration, each of the plurality of electronics modules comprising electrical connectors formed around an edge thereof; wherein each of the plural subsets of electrical connectors is configured for operative engagement of the electrical connectors of a corresponding one of the plurality of electronics modules. Optionally, the plural subsets of electrical connectors are further configured to hold the plurality of electronics modules in place within the cavity. Optionally, one or more of the electronics modules comprises a printed circuit assembly (PCA) comprising a printed circuit board (PCB), the PCA defining a perimeter configured for coupling with at least one adjacent PCM in a stacked arrangement, the PCA comprising one or more electronic components at least partially accommodated within the perimeter, the electronic components mounted in at least one cavity of the PCA, covered with an encapsulant, or both.

### Encapsulated, Stackable PCB Modules

In accordance with an aspect of the present invention, there is provided a stackable, encapsulated printed circuit assembly (PCA) and/or set thereof. The PCA comprises a printed circuit board (PCB) with a first set of components mounted to the top side and a second set of one or more components mounted to the bottom side. An encapsulant is conformally provided over the PCB and the sets of components. One or more channels are formed through the encapsulant as described below. Each of the one or more channels is configured to operatively couple a predetermined interior location of the PCA with a predetermined location on a surface of the encapsulant. The predetermined interior location is associated with a conductor of the PCB or a mounted component.

In accordance with embodiments of the invention, as an encapsulant is formed on and extends outward from the surface of a PCM, it defines one or more cavities of the PCM. For example, the encapsulant may define cavities which are occupied by electronic components previously mounted to the PCB. The encapsulant may further be formed overtop of these components, so that the cavities are sealed off. Additionally or alternatively, the encapsulant may define a cavity while also filling at least a portion of the cavity.

In embodiments of the present invention, the channels through the encapsulant are conductive channels terminating with an electrical connector located at the encapsulant surface. Plural channels and their corresponding electrical connectors may be provided on plural surfaces of the encapsulant, for example top and bottom surfaces, thereby facilitating stackability of the encapsulated PCA with other PCAs, which may in turn be encapsulated. Stackability may be vertical, horizontal, or a combination thereof. In various embodiments, the conductive channels may be regarded as forming at least part of the cavity defined by the encapsulant.

In accordance with embodiments of the present invention, there is provided a system of stackable, encapsulated PCB modules. Each module may comprise a PCB having components on one or both sides, and with an encapsulant formed around the PCB and components. The encapsulant is generally conformal to the PCB and components, and may provide one or more of: physical shielding, electrical insulation, and electromagnetic shielding. Electromagnetic shielding may be provided, for example, by embedding a conductive Faraday cage within or on the encapsulant, such that the conductive portions of the Faraday cage do not electrically interfere with the conductive vias. Generally, the encapsulant is used in providing PCB modules which are stackable.

In some embodiments, each conductive channel may be formed as follows. A via is formed in the encapsulant, for example by laser drilling, the via reaching to a predetermined location on the PCB or component thereof. A pad or other electrical connection exists at the predetermined location. A conductor is then provided which passes through the via from the predetermined location to the outer perimeter of the encapsulant. In some embodiments, the conductor is provided by coating the surface of the via with conductive material such as copper or solder, or by filling the via with conductive material, either molten or solid, such as a thin wire. A contact may then be formed at the end of each via for operative coupling to a circuit board or adjacent PCB module. In embodiments, the contact is a solder ball. In other embodiments, the contact may be a lead, pin, pad, aperture, or other electrical contact as would be readily understood by a worker skilled in the art.

In embodiments of the present invention, the encapsulant may be an insulating material such as a synthetic resin, which is capable of being applied to a mold in liquid form and solidifying into a desired shape, for example having flat surfaces to facilitate stackability. Desirable encapsulant materials may have good dimensional stability over time and temperature. Suitable encapsulant materials would be readily understood by a worker skilled in the art. For example, materials used in making individual microchip packages.

In some embodiments, the encapsulant may comprise physical features such as protrusions and/or depressions, which act as a key to facilitate appropriate stacking, interconnection and orientation of mating components. Interchangeable components may comprise similar physical features, while non-interchangeable components may comprise different features. In this manner, components cannot be easily physically coupled unless they are functionally compatible.

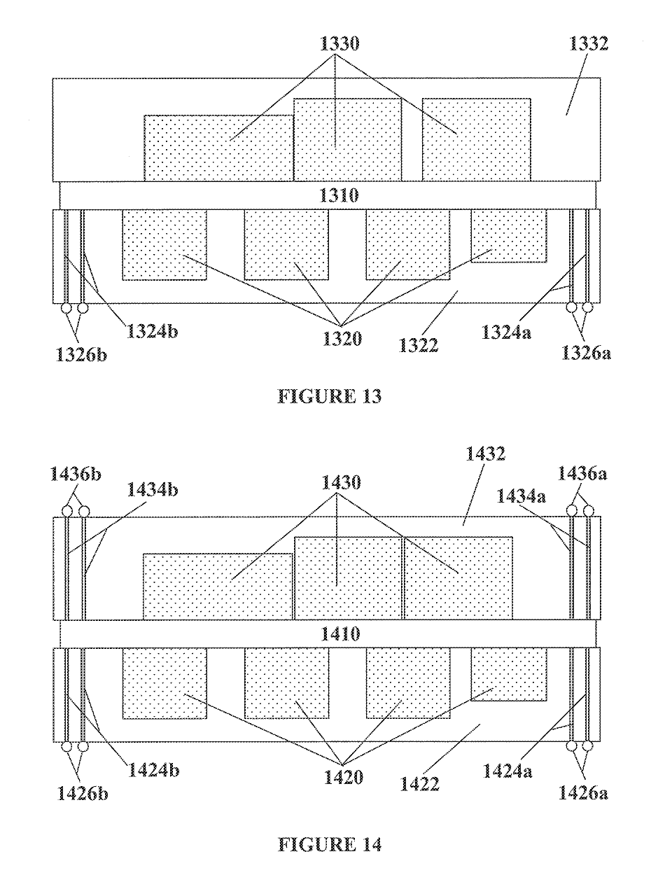

FIG. 13 illustrates, in cross section, a stackable, encapsulated printed circuit assembly (PCA) provided in accordance with an embodiment of the present invention. The PCA comprises a PCB 1310, upon which bottom side components 1320 and top side components 1330 are mounted. An encapsulant 1322 is formed overtop of at least a bottom surface of the PCB 1310 and the bottom side components 1320. An encapsulant 1332 is also formed overtop of at least a top surface of the PCB 1310 and the top side components 1330. Encapsulant may also optionally be provided overtop of side edges of the PCB 1310. As illustrated, the encapsulant results in substantially flat, parallel top and bottom surfaces of the PCA.

FIG. 13 further illustrates vias 1324a, 1324b, formed through the encapsulant and connecting with the PCB 1310, for example at pads or traces thereof. The vias comprise a conductor, such as a conductive coating formed on the sidewalls thereof. The vias are further electrically connected to connectors 1326a, 1326b, respectively, which may be solder balls, for example. As illustrated in FIG. 13, the conductive vias 1324a, 1324b, and the connectors 1326a, 1326b, are formed on one side of the PCA only. Such a PCA may be stacked on top of another PCA.

FIG. 14 illustrates, in cross section, a stackable, encapsulated printed circuit assembly (PCA) provided in accordance with another embodiment of the present invention. The PCA comprises a PCB 1410, upon which bottom side components 1420 and top side components 1430 are mounted. An encapsulant 1422 is formed overtop of at least a bottom surface of the PCB 1410 and the bottom side components 1420. An encapsulant 1432 is also formed overtop of at least a top surface of the PCB 1410 and the top side components 1430. Encapsulant may also optionally be provided overtop of side edges of the PCB 1410. As illustrated, the encapsulant results in substantially flat, parallel top and bottom surfaces of the PCA.

FIG. 14 further illustrates vias 1424a, 1424b, formed through the encapsulant 1422 and connecting with the bottom side of the PCB 1410, for example at pads or traces thereof. The vias comprise a conductor, such as a conductive coating formed on the sidewalls thereof. The vias are further electrically connected to connectors 1426a, 1426b, respectively, which may be solder balls, for example. FIG. 14 further illustrates vias 1434a, 1434b, formed through the encapsulant 1432 and connecting with the top side of the PCB 1410, for example at pads or traces thereof. The vias comprise a conductor, such as a conductive coating formed on the sidewalls thereof. The vias are further electrically connected to connectors 1436a, 1436b, respectively, which may be solder balls, for example. As illustrated in FIG. 14, the conductive vias 1424a, 1424b, 1434a, 1434b, and the connectors 1426a, 1426b, 1436a, 1436b, are formed on two opposing sides of the PCA. Such a PCA may be stacked in between two other PCAs.

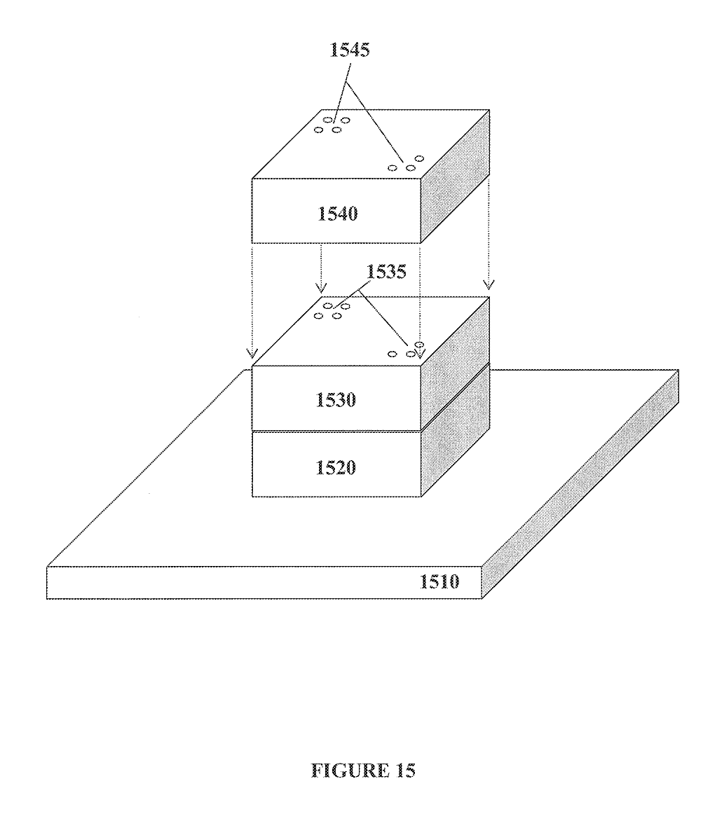

FIG. 15 illustrates a host PCB 1510 upon which a stack of encapsulated PCAs 1520, 1530, 1540 are formed. Each encapsulated PCA comprises mating electrical connectors, for example connectors 1545 of PCA 1540 and connectors 1535 of PCA 1530, formed one or two encapsulant surfaces, such that adjacent encapsulated PCAs are electrically interconnected.

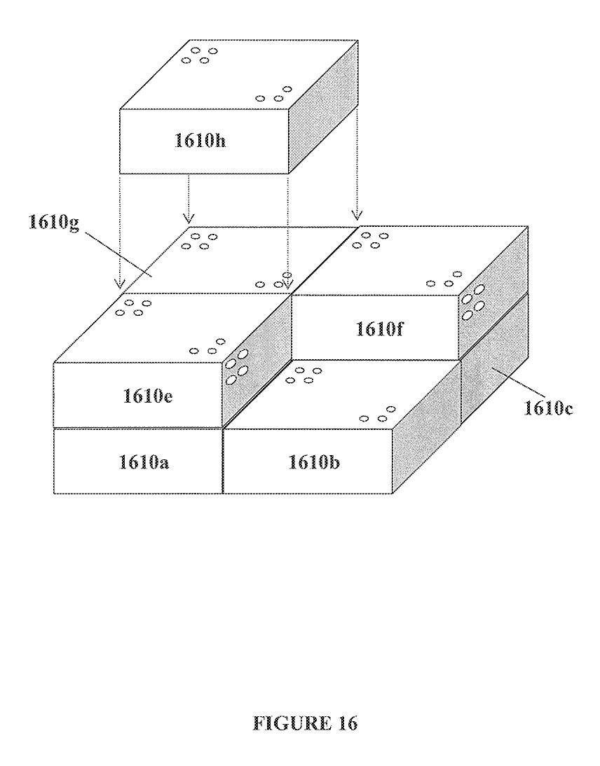

FIG. 16 illustrates a three-dimensional stack of encapsulated PCAs 1610a, 1610b, 1610c, 1610e, 1610f, 1610g, 1610h. Each encapsulated PCA comprises mating electrical connectors formed one or more encapsulant surfaces, such that adjacent encapsulated PCAs are electrically interconnected. Mating electrical connections may be formed on top, bottom, or side surfaces of the encapsulated PCAs.

The mating electrical connectors may be provided in a standardized pattern of locations, which is common between PCAs. Furthermore, each mating electrical connector location may correspond to a substantially standardized function, such as signal input, signal output, power, ground, generic, or the like. This facilitates modularity and interchangeability between PCAs.

In some embodiments, the encapsulant, which is conformally provided over the PCM, defines the at least one cavity of the PCM. Components may be fully accommodated within the cavity so defined by the encapsulant. In some embodiments, the encapsulant may both define and fill the cavity. All of the encapsulant may be provided at once. In this sense, the cavity may correspond to the space which is occupied by components which have been placed on the PCM prior to the encapsulant.

### Embodiments Encompassing Plural Aspects

Embodiments of the present invention may encompass a plurality of the aspects as described above. Such aspects relate to: Stackable PCAs with Cavities; Stackable Electronics Modules with Edge Contacts in the Socket Housing; and Encapsulated Stackable PCB Modules. Examples of such combination embodiments are described below.

In some embodiments, stackable PCAs with cavities may comprise an encapsulant, deposited only within the cavity or deposited in the cavity and overtop of a substantial portion of the PCA surface outside of the cavity. Channels may also be formed in the encapsulant as described herein to facilitate stackability. Such an arrangement may facilitate providing substantially uniform surfaces to PCAs to improve stackability.

In some embodiments, encapsulated PCB modules may comprise cavities formed in the encapsulant. The cavities may be configured to receive portions of adjacent PCMs provided in a stacking arrangement. The cavities may be configured to receive corresponding mating protrusions of adjacent PCMs. The protrusions may optionally be formed at least in part of encapsulating material. The cavities may be configured to house components therein, for example components mounted on an adjacent PCM, components mounted, for example by adhesive, in the encapsulant cavity and coupled to the host PCB using conductive vias, or a combination thereof. Components mounted in an encapsulant cavity, but not themselves encapsulated, are more easily serviced, while retaining a desired surface profile of the module to facilitate stackability. The unencapsulated components may be housed in sockets so that they can be easily accessed and interchanged.

In some embodiments, there is provided a printed circuit assembly (PCA) comprising a printed circuit board (PCB), the PCA defining a perimeter configured for coupling with at least one adjacent PCM in a stacked arrangement. The PCA comprises one or more electronic components at least partially accommodated within the perimeter, the electronic components mounted in at least one cavity of the PCA, covered with an encapsulant, or both.

In some embodiments, encapsulated PCB modules and/or stackable PCAs with cavities may be stacked in an appropriate socket housing. For example, the encapsulated PCB modules may include edge contacts operatively coupled to signal channels routed through the encapsulant to the PCB and/or components thereof. The use of cavities may facilitate closer spacing of PCAs, thereby allowing more modules to be stacked in the socket.

In some embodiments, plural stacked PCAs with cavities may be encapsulated to form an encapsulated PCB module. Again, the use of cavities may facilitate providing an encapsulated module with an adequately low profile.

As an example, a set of interchangeable modules may comprise plural memory modules, each with a different amount of available memory, a different type of memory, such as volatile or non-volatile memory, a different access speed, a different number of read-write cycles, or the like. An appropriate memory module may then be selected and included based on factors such as performance requirements and cost.

As another example, a set of interchangeable modules may comprise plural digital wireless communication modules. Each digital wireless communication module may be capable of generating signals in accordance with one or more predetermined wireless communication protocols, such as a cellular-type protocol such as CDMA, GSM, Wi-Fi™ or WiMAX™ protocol, or the like. The signals may then be conveyed to and from a further processing module, analog radiofrequency electronics module, antenna, and the like, as would be readily understood by a worker skilled in the art. Each digital wireless communication module may further be configured to communicate, via a substantially standardized interface, a substantially standardized protocol, and a substantially standardized command set, with other electronics components coupled to the module such as a microprocessor, microcontroller, or the like. Such other electronics may be provided in another, possibly adjacent module.

Other sets of interchangeable modules may be provided. Each module of the set may be interchangeable with one or more other modules of the set performing similar or analogous functions. In some embodiments, different modules performing substantially different functions may be interchangeable, thereby facilitating greater customization.

It is obvious that the foregoing embodiments of the invention are examples and can be varied in many ways. Such present or future variations are not to be regarded as a departure from the spirit and scope of the invention, and all such modifications as would be obvious to one skilled in the art are intended to be included within the scope of the following claims.

What is claimed is:

1. A printed circuit module (PCM) comprising a printed circuit board (PCB), the PCM defining at least one cavity and configured for operative coupling with an adjacent PCM in a stacked arrangement, wherein the at least one cavity is configured to at least partially accommodate one or more electronic components, the electronic components operatively mounted either on the PCB or on a PCB of the adjacent PCM.

2. The PCM according to claim 1, wherein the PCM comprise a perimeter configured for coupling with the adjacent PCM, wherein the electronic components are at least partially accommodated within the perimeter.

3. The PCM according to claim 1, further comprising an encapsulant conformally provided over at least the PCB.

4. The PCM according to claim 3, wherein the electronic components are mounted on the PCB, and wherein the encapsulant is further conformally provided over the electronic components.

5. The PCM according to claim 4, further comprising one or more channels formed through the encapsulant, each of the one or more channels configured to operatively couple a predetermined location of the PCM with a predetermined location on an outer surface of the encapsulant, the predetermined interior location associated with at one of the one or more components.

6. The PCM according to claim 5, wherein the one or more channels comprise a laser-drilled via comprising a conductive coating.

7. The PCM according to claim 4, wherein an outer surface of the encapsulant is shaped to physically facilitate stacking of the PCM with the adjacent PCM.

8. The PCM according to claim 1, wherein the PCB comprises a surface layer and an interior layer, and wherein the at least one cavity is formed in the surface layer and extends to the interior layer.

9. The PCM according to claim 1, wherein the PCM comprises physical and electrical interface characteristics common to a family of interchangeable PCMs, each of the family of interchangeable PCMs having different functional characteristics.

10. The PCM according to claim 1, wherein the at least one cavity comprises sidewalls defined by spacers mounted to the PCB.

11. The PCM according to claim 1, wherein at least one of the electronic components is either mounted on the PCB of the adjacent PCM or at least partially accommodated within a cavity of the adjacent PCM, thereby avoiding mounting of the at least one electronic component within a cavity having a depth of at least the height of the at least one electronic component.

12. A system of two or more printed circuit modules (PCMs) configured for coupling in a stacked arrangement, at least one of the PCMs comprising a printed circuit board (PCB), the PCM defining at least one cavity and configured for operative coupling with an adjacent PCM in a stacked arrangement, wherein the at least one cavity is configured to at least partially accommodate one or more electronic components, the electronic components operatively mounted either on the PCB or on a PCB of the adjacent PCM.

13. The system according to claim 12, wherein at least one of the two or more PCMs comprises a printed circuit board (PCB) having a surface layer and an interior layer, wherein at least a portion of the cavity is formed in the surface layer and extends to the interior layer, and wherein the surface layer is configured for coupling with the adjacent PCM in the stacked arrangement.

14. The system according to claim 12, wherein the cavity is defined by a first PCM of the two or more PCMs, wherein a second cavity is defined by a second PCM of the two or more PCMs, the second PCM adjacent to the first PCM, and wherein the first cavity faces and is in communication with the second cavity when the first PCM and the second PCM are in the stacked arrangement, at least one of the electronic components accommodated partially by the first cavity and partially by the second cavity.

15. A printed circuit assembly (PCA) comprising:
a) a printed circuit board (PCB);
b) a set of one or more components mounted to a side of the PCB;
c) an encapsulant conformally provided over the PCB and the set of one or more components; and
e) one or more channels formed through the encapsulant, each of the one or more channels configured to operatively couple a predetermined interior location of the PCA with a predetermined location on a surface of the encapsulant, the predetermined interior location associated with a component of the set of one or more components or a conductor of the PCB.

16. The PCA according to claim 15, further comprising a second set of one or more components mounted on an opposite side of the PCB, and wherein the encapsulant is conformally provided over the second set of one or more components.

17. The PCA according to claim 15, wherein at least one of the one or more channels is a conductive channel, the PCA further comprising an electrical connector located at the predetermined location on the surface of the encapsulant.

18. The PCA according to claim 15, wherein one of the one or more channels terminates at a first surface of the encapsulant, and another of the one or more channels terminates at a second surface of the encapsulant, the second surface opposite the first surface, thereby facilitating stacking of the PCA between two printed circuit modules (PCMs).

19. A modular electronics system comprising:
a) a socket comprising a first set of electrical connectors configured for interfacing with a printed circuit board; a cavity; and plural subsets of electrical connectors arranged in a stacked configuration along one or more interior sidewalls of the cavity, the first set of electrical connectors operatively coupled with the plural subsets of electrical connectors; and
b) a plurality of electronics modules configured for insertion in the cavity in a stacked configuration, each of the plurality of electronics modules comprising electrical connectors formed around an edge thereof, each of the electronics modules comprising a PCM, said PCM comprising:
a printed circuit board (PCB), the PCM defining at least one cavity and configured for operative coupling with an adjacent PCM in a stacked arrangement, wherein the at least one cavity is configured to at least partially accommodate one or more electronic components, the electronic components operatively mounted either on the PCB or on a PCB of the adjacent PCM;
wherein each of the plural subsets of electrical connectors is configured for operative engagement of the electrical connectors of a corresponding one of the plurality of electronics modules.
